(19) United States
(12) Patent Application Publication
(10) Pub. No.: US 2025/0351400 A1
(43) Pub. Date: Nov. 13, 2025

(54) METHOD FOR MANUFACTURING SEMICONDUCTOR DEVICE AND SEMICONDUCTOR DEVICE MANUFACTURED THEREBY

(71) Applicant: National Tsing Hua University, Hsinchu City (TW)

(72) Inventors: Yu-Lun CHUEH, Hsinchu City (TW); Xin-Rui LIU, Taichung City (TW); Sumayah Shakil WANI, Hsinchu City (TW)

(73) Assignee: National Tsing Hua University, Hsinchu City (TW)

(21) Appl. No.: 19/050,503

(22) Filed: Feb. 11, 2025

(30) Foreign Application Priority Data
May 10, 2024 (TW) 113117334
Nov. 13, 2024 (TW) 113143600

(51) Int. Cl. H10D 30/01; H10D 30/47; H10D 62/00; H10D 62/80

(52) U.S. Cl. CPC H10D 30/017; H10D 30/481; H10D 62/01; H10D 62/883

(57) ABSTRACT

A method for manufacturing a semiconductor device includes: forming a two-dimensional material layer made of transition metal dichalcogenides on a semiconductor substrate unit; forming two lower metallic layers made of first metallic material and spaced apart on the two-dimensional material layer; forming two upper metallic layers made of second metallic material respectively on the two lower metallic layers so as to form two double-layer metal structures; and subjecting the two double-layer metal structures to a selective annealing process and cooling to room temperature. The semiconductor device made by the method is also provided.

### CROSS-REFERENCE TO RELATED APPLICATION

This application claims priority to Taiwanese Invention Patent Application Nos. 113117334 and 113143600, filed on May 10, 2024 and Nov. 13, 2024, respectively. The entire disclosure of each of the Taiwanese Invention Patent applications is incorporated by reference herein.

### FIELD

The present disclosure relates to a method for manufacturing a semiconductor device. The present disclosure also relates to a semiconductor device manufactured by the method.

### BACKGROUND

Since transition metal dichalcogenides (abbreviated as TMDs hereinafter) are formed as a two-dimensional layered structure with thickness of only a single molecular layer, the band gap of TMDs can be converted from an indirect band gap of a three-dimensional structure to a direct band gap. The TMDs with the two-dimensional layered structure, after being made into a field-effect transistor, have an excellent on/off current ratio, and thus attracted much attention from the industry in recent years. Common TMDs include semiconductor two-dimensional materials such as molybdenum disulfide (MoS₂), tungsten disulfide (WS₂), molybdenum diselenide (MoSe₂), tungsten diselenide (WSe₂), etc.

Referring to FIG. 1, Taiwanese Invention Patent Application Publication No. TW 202109882 A, corresponding to U.S. Patent Application Publication No. US20210057524A1, discloses a conventional semiconductor device 1 which includes a substrate 11, a semiconductor two-dimensional material (e.g., MoS₂) layer 12 disposed on the substrate 11, a source film layer structure 13S and a drain film layer structure 13D that are spaced apart and respectively disposed on a source region 12S and a drain region 12D of the semiconductor two-dimensional material layer 12, a gate dielectric layer 14 that extends along a channel region 12C of the semiconductor two-dimensional material layer 12 and that partially exposes the source film layer structure 13S and the drain film layer structure 13D, and a gate electrode 15 disposed on the gate dielectric layer 14. The source film layer structure 13S and the drain film layer structure 13D have, stacked in sequence from bottom to top, respectively, conductive two-dimensional material layers 131S, 131D each containing group IV elements, separation metal layers 132S, 132D, and electrode metal layers 133S, 133D. Each of the conductive two-dimensional material layers 131S, 131D is made of germanene or stanene. Each of the separation metal layers 132S, 132D may be made of aluminum (Al), bismuth (Bi), cadmium (Cd), chromium (Cr), iridium (Ir), niobium (Nb), tantalum (Ta), tellurium (Te), tungsten (W) or other metallic materials that do not form an alloy with each of the conductive two-dimensional material layers 131S, 131D. Each of the electrode metal layers 133S, 133D may be made of indium (In), lead (Pb), copper (Cu), silver (Ag), gold (Au), nickel (Ni), platinum (Pt), cobalt (Co), rhodium (Rh), iron (Fe), ruthenium (Ru), manganese (Mn), molybdenum (Mo), vanadium (V), titanium (Ti), zirconium (Zr), hafnium (Hf), magnesium (Mg) or other metallic materials that will form an alloy with each of the conductive two-dimensional material layers 131S, 131D.

The current density of transistors including TMDs is often limited by contact resistance because in a process of manufacturing such transistors, semiconductor two-dimensional materials of TMDs are easily damaged by high energy generated during formation of the electrode metal layers and form defects, causing a pinning effect at the fermi-level, and ultimately resulting in the Schottky barrier cannot be effectively reduced.

In view of the above, those skill in the art strive to improve the manufacturing method and structure of semiconductor devices so as to effectively reduce contact resistance and to increase current density.

### SUMMARY

Therefore, an object of the present disclosure is to provide a method for manufacturing a semiconductor device and a semiconductor device manufactured thereby that can alleviate at least one of the drawbacks of the prior art.

According to an aspect of the present disclosure, the method for manufacturing a semiconductor device includes the steps of:
(a) forming a two-dimensional material layer made of transition metal dichalcogenides on a semiconductor substrate unit;
(b) forming two lower metallic layers made of a first metallic material on the two-dimensional material layer, the two lower metallic layers being spaced apart from each other;
(c) forming two upper metallic layers made of a second metallic material respectively on the two lower metallic layers, so as to form two double-layer metal structures each including one of the upper metallic layers and a respective one of the two lower metallic layers; and
(d) subjecting the two double-layer metal structures to a selective annealing process, followed by cooling to room temperature, so as to form the two double-layer metal structures into a treated configuration. The first metallic material has a first melting point, the second metallic material has a second melting point, and the first melting point is lower than the second melting point. The treated configuration has one of a first configuration and a second configuration. The first configuration is obtained by alloying of the first metallic material and the second metallic material in the two double-layer metal structures during the selective annealing process to obtain two first alloyed structures, and cooling the two first alloyed structures to room temperature in a way that the two first alloyed structures are precipitated into two single crystal parts of the first metallic material and two first metal electrode layers of the second metallic material. The two single crystal parts of the first metallic material are formed over the two-dimensional material layer and are spaced apart from each other. Each of the two first metal electrode layers of the second metallic material is in contact with a respective one of the two single crystal parts of the first metallic material. The second configuration is obtained by alloying of the first metallic material and the second metallic material in the two double-layer metal structures during the selective annealing process to obtain two second alloyed structures, and cooling the two second alloyed structures to room temperature in a way that the second alloyed structures are precipitated into two single crystal parts of intermetallic compound which are from at least one portion of the first metallic material and a first portion of the second metallic material in the two double-layer metal structures, and two second metal electrode layers of the second metallic material which are from a second portion of the second metallic material in the two double-layer metal structures. The two single crystal parts of the intermetallic compound are formed over the two-dimensional material layer and are spaced apart from each other. Each of the two second metal electrode layers of the second metallic material is in contact with a respective one of the two single crystal parts of the intermetallic compound.

According to another aspect of the present disclosure, the semiconductor device includes a semiconductor substrate unit; a two-dimensional material layer formed on the semiconductor substrate unit and made of transition metal dichalcogenides; two single crystal parts formed over the two-dimensional material layer and are spaced apart from each other, the two single crystal parts being made of one of a first metallic material and an intermetallic compound that is composed of the first metallic material and a second metallic material; and two metal electrode layers made of the second metallic material, each of the two metal electrode layers being in contact with a respective one of the two single crystal parts. The first metallic material has a first melting point, the second metallic material has a second melting point, and the first melting point is lower than the second melting point.

### BRIEF DESCRIPTION OF THE DRAWINGS

Other features and advantages of the present disclosure will become apparent in the following detailed description of the embodiment(s) with reference to the accompanying drawings. It is noted that various features may not be drawn to scale.

FIG. 1 is a schematic view illustrating a conventional semiconductor device disclosed in Taiwanese Invention Patent Application Publication No. TW 202109882 A.

FIGS. 2A to 2D are schematic views respectively illustrating steps (a) to (d) of a method for manufacturing a semiconductor device according to a first embodiment of the present disclosure.

FIGS. 3A to 3H are schematic views respectively illustrating the detailed procedures of step (a) of the method for manufacturing a semiconductor device according to the first embodiment of the present disclosure.

FIG. 4 is a schematic view illustrating the process of implementing step (d) of the method for manufacturing a semiconductor device according to the first embodiment of the present disclosure, and a semiconductor device obtained thereby.

FIG. 5 is a schematic view illustrating the process of implementing step (d) of the method for manufacturing a semiconductor device according to a second embodiment of the present disclosure, and a semiconductor device obtained thereby.

FIG. 6 is a schematic view illustrating the process of implementing step (d) of the method for manufacturing a semiconductor device according to a third embodiment of the present disclosure, and a semiconductor device obtained thereby.

FIG. 7 is a diagram showing Raman spectra of semiconductor devices obtained by manufacturing methods of Example 1 (E1) and Comparative Example 1 (CE1), respectively.

FIGS. 8A and 8B are transmission electron microscopy (TEM) images respectively showing cross-sectional views of the semiconductor device obtained by the manufacturing method of E1.

FIG. 9 is a high-resolution transmission electron microscopy (HRTEM) image showing a cross-sectional view of Bi single crystal parts of the semiconductor device obtained by the manufacturing method of E1.

FIG. 10A is a graph showing current density versus gate voltage, illustrating the transfer characteristic for the semiconductor devices obtained by the manufacturing methods of E1 and CE1, in which the current density at the left side is in log scale and the current density at the right side is in linear scale.

FIG. 10B is a graph showing total resistance (Rₜₒₜₐₗ) versus channel length (L), where the y-intercept value is twice the contact resistance (2R_{c}), for the semiconductor devices obtained by the manufacturing methods of E1 and CE1.

FIG. 11 is a diagram showing grazing-incidence X-ray diffraction for the crystal structures of the semiconductor devices obtained by the manufacturing methods of Example 3 (E3), Comparative Example 2 (CE2) and Comparative Example 3 (CE3).

FIG. 12A is a TEM image showing a cross-sectional view of the semiconductor device obtained by the manufacturing method of CE2.

FIG. 12B is a TEM image showing a cross-sectional view of the semiconductor device obtained by the manufacturing method of Comparative Example 4 (CE4).

FIG. 13A is a TEM image, including a partially enlarged TEM image inserted in the lower right corner thereof, showing a cross-sectional view of the semiconductor device obtained by the manufacturing method of E2.

FIG. 13B is a TEM image at a high magnification showing a cross-sectional view of Bi₃Ni single crystal parts of the semiconductor device obtained by the manufacturing method of E2.

FIG. 14 is a TEM image showing a cross-sectional view of a Bi contact layer that is in contact with a MoS₂ two-dimensional material layer of the semiconductor device obtained by the manufacturing method of Example 3 (E3).

FIG. 15A is a graph of drain current versus gate voltage, illustrating the transfer characteristic for the semiconductor devices obtained by the manufacturing methods of CE2 and CE4.

FIG. 15B is a graph of drain current versus gate voltage, illustrating the transfer characteristic for the semiconductor devices obtained by the manufacturing methods of CE2 and E2.

FIG. 15C is a graph of drain current versus gate voltage, illustrating the transfer characteristic for the semiconductor devices obtained by the manufacturing methods of CE2 and E3.

FIG. 16A is a graph of total resistance versus channel length, illustrating the contact resistance for the semiconductor device obtained by the manufacturing method of CE2.

FIG. 16B is a graph of total resistance versus channel length, illustrating the contact resistance for the semiconductor device obtained by the manufacturing method of E3.

FIGS. 17A and 17B are each a graph of drain current density versus gate voltage, illustrating the transfer characteristic for the semiconductor device obtained by the manufacturing method of CE2 before and after being subjected to a rapid thermal annealing (RTA) process under different temperatures.

FIGS. 18A and 18B are each a graph of drain current density versus gate voltage, illustrating the transfer characteristic for the semiconductor device obtained by the manufacturing method of E3 before and after being subjected to the RTA process under different temperatures.

FIGS. 19A and 19B are each a graph of drain current density versus gate voltage, illustrating the transfer characteristic for the semiconductor device obtained by the manufacturing method of E1 before and after being subjected to the RTA process under different temperatures.

FIG. 20 is a graph of on-current density versus annealing temperature which is derived based on the data shown in FIGS. 17 to 19.

FIG. 21A is a graph of drain current density versus gate voltage, illustrating the transfer characteristic for the semiconductor devices obtained by the manufacturing methods of CE2 and E3, in which the current density at the left side is in log scale and the current density at the right side is in linear scale.

FIG. 21B is a graph of drain current density versus drain voltage, illustrating the output characteristic for the semiconductor device obtained by the manufacturing method of E3.

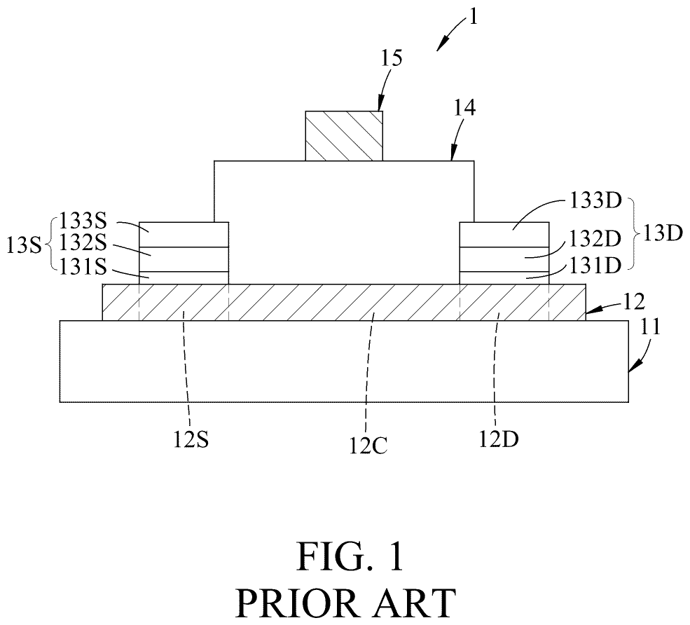

### DETAILED DESCRIPTION

Before the present disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

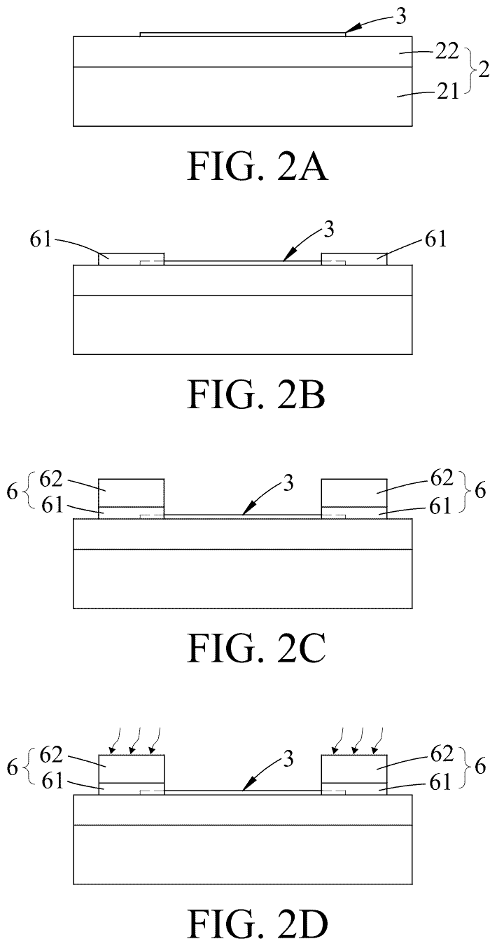

Referring to FIGS. 2A to 2D, 3A to 3H and 4, the present disclosure provides a method for manufacturing a semiconductor device according to the first embodiment, and a semiconductor device manufactured thereby. The method for manufacturing a semiconductor device of the first embodiment includes steps (a) to (d).

As shown in FIG. 2A, in step (a), a two-dimensional material layer 3 made of transitional metal dichalcogenides (TMDs) is formed on a semiconductor substrate unit 2. The semiconductor substrate unit 2 includes a doped semiconductor substrate 21 and a dielectric layer 22 formed on the doped semiconductor substrate 21. In the first embodiment, the doped semiconductor substrate 21 and the dielectric layer 22 are respectively exemplified by an N-type silicon substrate heavily doped with phosphorus (P) and a silicon dioxide (SiO₂) layer, but are not limited thereto. The TMDs suitable for the first embodiment may be selected from MoS₂, WS₂, MoSe₂ or WSe₂. In the first embodiment, the TMDs are exemplified by an N-type semiconductor material of MoS₂, but is not limited thereto. To be specific, in the first embodiment, the N-type silicon substrate and the SiO₂ layer respectively serve as a bottom gate and a gate dielectric layer of a semiconductor device obtained by the method of the present disclosure, and the two-dimensional material layer 3 serves as a channel layer of the semiconductor device.

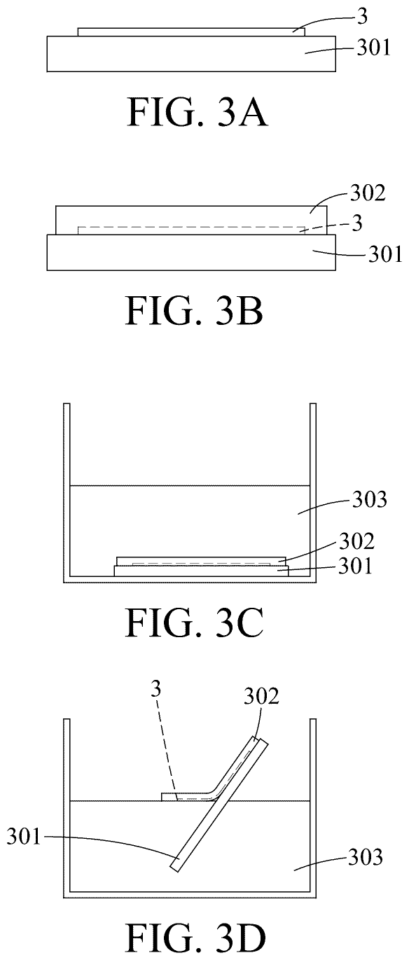

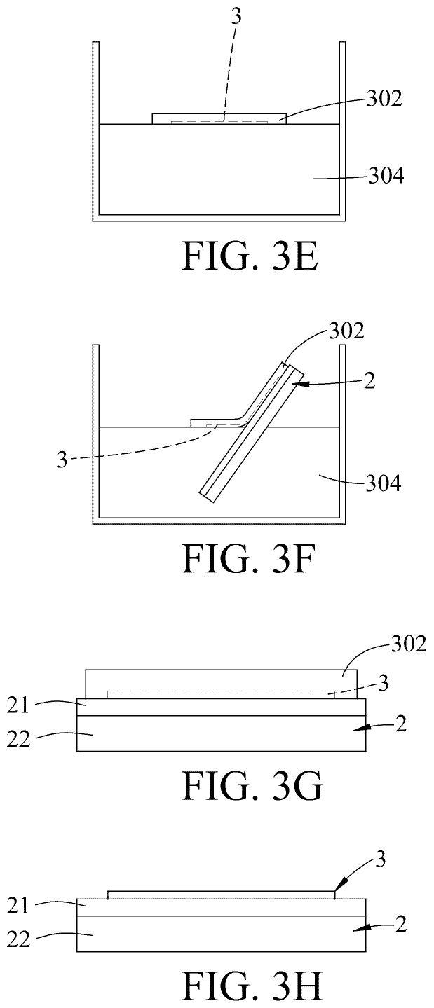

In step (a) of the method of the first embodiment, the two-dimensional material layer 3 is formed on the semiconductor substrate unit 2 by a wet transfer process, as shown in FIGS. 3A to 3H. To be specific, the two-dimensional material layer 3 is first formed on a sapphire substrate 301 by chemical vapor deposition (CVD) (see FIG. 3A). Next, as shown in FIG. 3B, the sapphire substrate 301, on which the two-dimensional material layer 3 is formed, is covered with a poly(methyl methacrylate) (abbreviated as PMMA hereinafter) layer 302. Thereafter, the sapphire substrate 301 covered with the PMMA layer 302 is immersed in a 1 M potassium hydroxide (KOH) aqueous solution 303, so that a periphery of the PMMA layer 302 is etched by the KOH aqueous solution 303 in a direction toward the two-dimensional material layer 3. After separation of the periphery of the PMMA layer 302 from the sapphire substrate 301, the two-dimensional material layer 3 is gradually desorbed from the sapphire substrate 301 by the surface tension and buoyancy attributed to the KOH aqueous solution 303 (see FIG. 3D). Afterwards, the two-dimensional material layer 3 covered with the PMMA layer 302 is placed on deionized water 304 (see FIG. 3E), and then the semiconductor substrate unit 2 is placed into the deionized water 304 to lift up the two-dimensional material layer 3 covered with the PMMA layer 302 (see FIG. 3F). Subsequently, the PMMA layer 302, the two-dimensional material layer 3 and the semiconductor substrate unit 2 are placed on a heating plate (not shown), and then dried at 100° C. (see FIG. 3G). After that, the PMMA layer 302, the two-dimensional material layer 3 and the semiconductor substrate unit 2 are, in sequence, entirely immersed in acetone (in such order) at 60° C. for 10 minutes to remove the PMMA layer 302 (see FIG. 3H), followed by immersion in isopropyl alcohol (IPA) to remove the acetone and then blow drying with nitrogen (N₂), thereby completing step (a) of the method.

As shown in FIG. 2B, in step (b), two lower metallic layers 61, which are made of a first metallic material, are formed on the two-dimensional material layer 3. The two lower metallic layers 61 are spaced apart from each other.

As shown in FIG. 2C, in step (c), two upper metallic layers 62 made of a second metallic material are respectively formed on the two lower metallic layers 61, so as to form two double-layer metal structures 6 each including one of the upper metallic layers 62 and a respective one of the two lower metallic layers 61.

As shown in FIG. 2D, in step (d), the double-layer metal structures 6 are subjected to a selective annealing process, followed by cooling to room temperature, so as to form the double-layer metal structures 6 into a treated configuration. The selective annealing process is a laser annealing technique conducted on a top surface of each of the double-layer metal structures 6, and a laser light used in the laser annealing technique has a predetermined wavelength ranging from 800 nm to 1 mm. It should be noted that, the selective annealing process disclosed herein means that the thermal energy of the laser light having the range of predetermined wavelength can be absorbed by the lower metallic layer 61 and the upper metallic layer 62 of each of the double-layer metal structures 6, but cannot be absorbed by the two-dimensional material layer 3. Therefore, during the selective annealing process, each of the double-layer metal structures 6 can undergo phase transformation due to use of the thermal energy of the laser light, and the two-dimensional material layer 3 partially covered by each of the double-layer metal structures 6 is not damaged by the thermal energy of the laser light.

According to the present disclosure, the first metallic material has a first melting point, the second metallic material has a second melting point, and the first melting point is lower than the second melting point. The first metallic material is selected from Bi, Sb, In, Sn or Pb, and the second metallic material is selected from Au, Ni, Pt, Pd, Ti or Al. However, there is a requirement that, when the first metallic material is Bi or Sn, Al is excluded as the second metallic material; and when the first metallic material is Pb, Ni, Ti and Al are excluded as the second metallic material.

In certain embodiments, in each of the double-layer metal structures 6, the lower metallic layer 61 has a first thickness ranging from 1 nm to 20 nm, and the upper metallic layer 62 has a second thickness ranging from 10 nm to 100 nm. In certain embodiments, in each of the double-layer metal structures 6, the first thickness of the lower metallic layer 61 ranges from 2 nm to 12 nm, and the second thickness of the upper metallic layer 62 ranges from 35 nm to 75 nm. In the first embodiment, the first metallic material is Bi, and the second metallic material is Au.

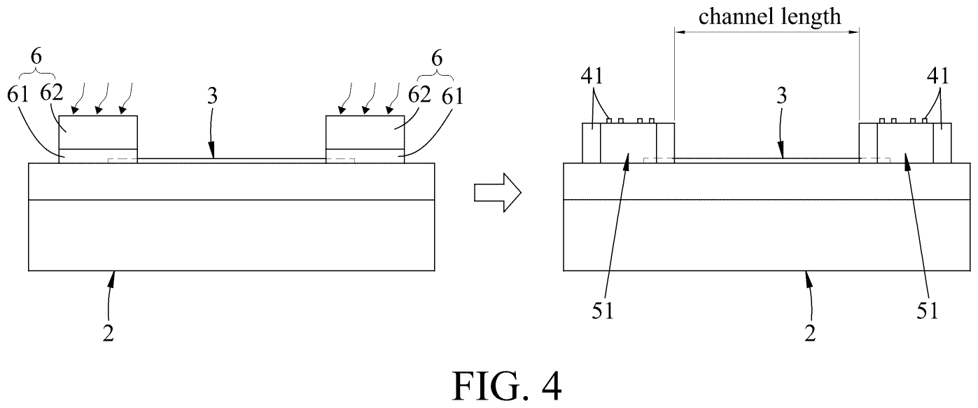

To be specific, referring to FIG. 4, the treated configuration of the first embodiment is obtained by alloying of the first metallic material and the second metallic material in the two double-layer metal structures 6 during the selective annealing process to obtain two first alloyed structures (not shown), and cooling the two first alloyed structures to room temperature in a way that the two first alloyed structures are precipitated into two single crystal parts of the first metallic material 41 (Bi) and two first metal electrode layers 51 of the second metallic material (Au). The two single crystal parts of the first metallic material 41 are formed over the two-dimensional material layer 3 and spaced apart from each other, and each of the first metal electrode layers 51 is in contact with a respective one of the two single crystal parts of the first metallic material 41. Thus, it is known that the single crystal parts of the first metallic material 41 are made of the first metallic material (Bi), and the metal electrode layers 51 of the second metallic material are made of the second metallic material (Au). Referring to FIG. 4, in some embodiments, after cooling to room temperature, each of the two first alloyed structures is precipitated into a plurality of single crystal parts of the first metallic material 41 and a first metal electrode layer 51 of the second metallic material.

It should be mentioned herein that, in the first embodiment, the thickness of the lower metallic layer 61 of each of the double-layer metal structures 6 determines the position of the single crystal parts of the first metallic material 41 precipitated therefrom following the selective annealing process and the cooling to room temperature. To be specific, when the lower metallic layer 61 having the first thickness is relatively thick, after the selective annealing process and cooling to room temperature, the single crystal(s) of the first metallic material 41 (Bi) obtained from the lower metallic layer 61 of each of the double-layer metal structures 6 tend to precipitate at the periphery and on an upper surface of the respective first metal electrode layer 51 of the second metallic material (Au) (see FIG. 4). In contrast, when the lower metallic layer 61 having the first thickness is relatively thin, after the selective annealing process and cooling to room temperature, the single crystal(s) of the first metallic material 41 (Bi) obtained from the lower metallic layer 61 of each of the double-layer metal structures 6 tend to precipitate on a lower surface of the respective first metal electrode layer 51 of the second metallic material (Au) so as to be in direct contact with the two-dimensional material layer 3.

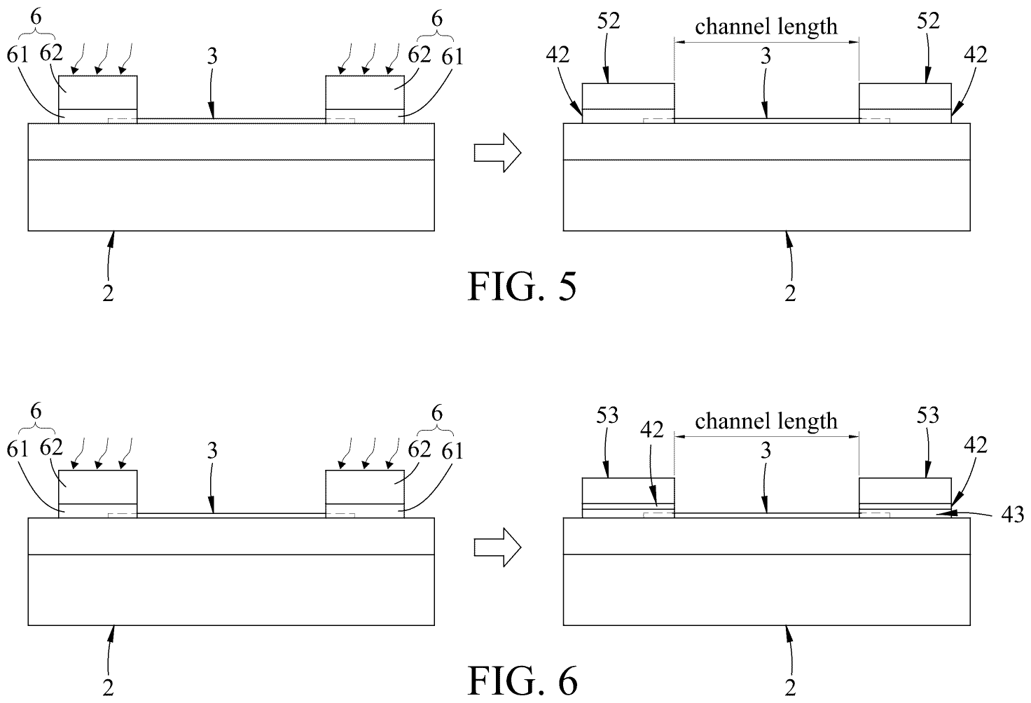

Referring to FIG. 5, a second embodiment of the method for manufacturing a semiconductor device according to the present disclosure and the semiconductor manufactured thereby are substantially similar to those of the first embodiment, except that in the second embodiment, the second metallic material is Ni. To be specific, the treated configuration of the second embodiment is obtained by alloying of the first metallic material and the second metallic material in the two double-layer metal structures 6 during the selective annealing process to obtain two second alloyed structures (not shown), and cooling the two second alloyed structures to room temperature in a way that the two second alloyed structures are precipitated into two single crystal parts of intermetallic compound 42 which are from at least one portion of the first metallic material and a first portion of the second metallic material in the two double-layer metal structures 6, and two second metal electrode layers 52 of the second metallic material which are from a second portion (i.e., a remaining portion) of the second metallic material in the two double-layer metal structures 6. The two single crystal parts of the intermetallic compound 42 are formed over the two-dimensional material layer 3 and are spaced apart from each other, each of the two second metal electrode layers 52 of the second metallic material is in contact with a respective one of the two single crystal parts of the intermetallic compound 42. Thus, it is known that each of the single crystal parts of the intermetallic compound 42 is made of the at least one portion of the first metallic material and the first portion of the second metallic material.

To be specific, the intermetallic compound of each of the single crystal parts 42 is Bi₃Ni. Each of the single crystal parts of the intermetallic compound 42 includes a plurality of Bi₃Ni layers (not shown) stacked along a thickness direction of the two-dimensional material layer 3, and each of the second metal electrode layers 52 of the second metallic material is formed on an upper surface of a respective one of the single crystal parts of the intermetallic compound 42 (Bi₃Ni).

Referring to FIG. 6, a third embodiment of the method for manufacturing a semiconductor device according to the present disclosure and the semiconductor manufactured thereby are substantially similar to those of the second embodiment, except that in step (d) of the third embodiment, after cooling the two second alloyed structures to room temperature, two Bi contact layers 43 are further formed from a remaining portion of the first metallic material in the two double-layer metal structures 6. Each of the two Bi contact layers 43 is sandwiched between the two-dimensional material layer 3 and the respective one of the two single crystal parts of the intermetallic compound 42 (Bi₃Ni).

The present disclosure will be described by way of the following examples. However, it should be understood that the following examples are intended solely for the purpose of illustration and should not be construed as limiting the present disclosure in practice.

### Example 1 (E1)

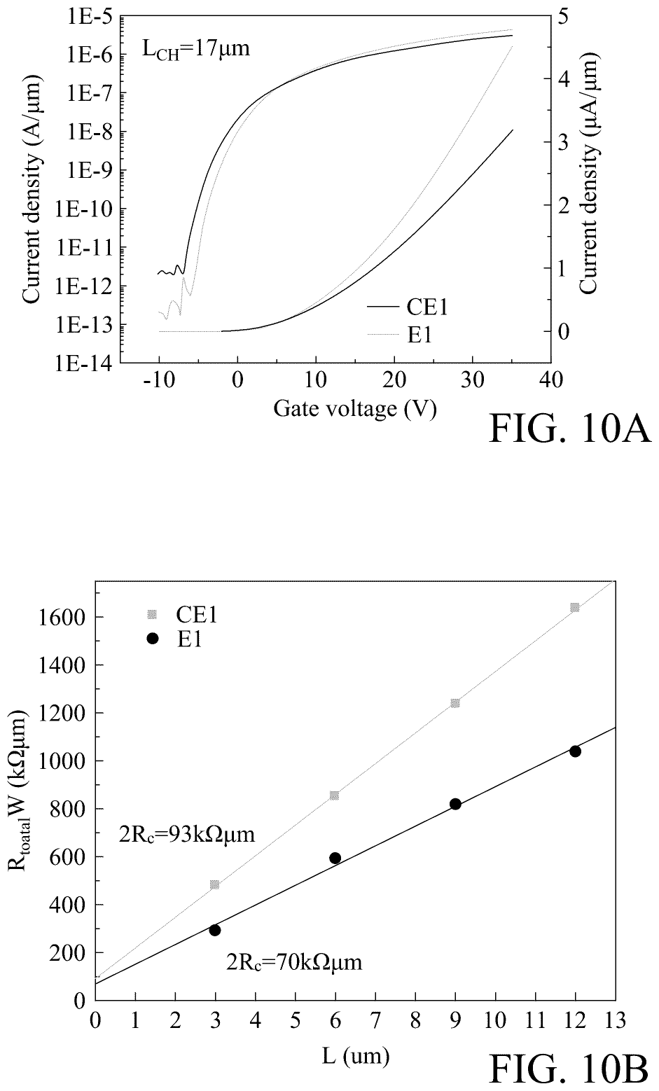

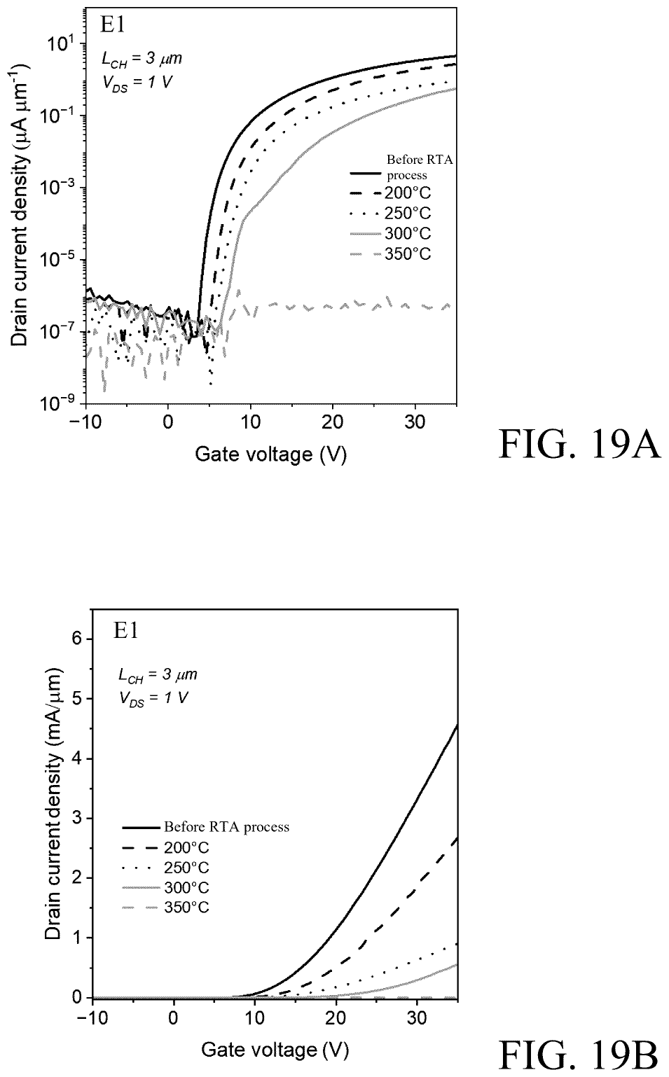

The method for manufacturing a semiconductor device of E1 was implemented according to the aforesaid first embodiment of the present disclosure. First, a MoS₂ two-dimensional material layer was formed on a semiconductor substrate unit (including a SiO₂ layer and an N-type silicon substrate that was heavily doped with phosphorus) by the wet transfer process. The MoS₂ two-dimensional material layer was formed on the SiO₂ layer. Next, a patterned photoresist layer was formed on the MoS₂ two-dimensional material layer opposite to the N-type silicon substrate by a photolithography process, so as to partially expose two regions of the MoS₂ two-dimensional material layer which were spaced apart from each other. Thereafter, a 10 nm Bi layer and a 50 nm Au layer were sequentially deposited on the two regions of the MoS₂ two-dimensional material layer exposed from the patterned photoresist layer using an electron beam evaporator at an working pressure ranging from 5×10⁻⁶ torr to 1.2×10⁻⁵ torr. Afterwards, the patterned photoresist layer was removed to obtain two double-layer metal structures. Subsequently, the two double-layer metal structures were subjected to a selective annealing process conducted using Diamond E-1000 CO₂ laser annealing equipment purchased from Coherent Corp., Pennsylvania, USA to obtain two alloyed structures, followed by a cooling process for cooling the two alloyed structures to room temperature, thereby obtaining a semiconductor device of E1. The parameters for the selective annealing process of E1 were shown in Table 1 below. It should be noted that, in the manufacturing method of E1, the MoS₂ two-dimensional material layer served as a channel layer of the semiconductor device, and the channel layer had a length which is defined between the two regions of the MoS₂ two-dimensional layer, and which is of 17.0 μm (see FIG. 10A) or 3.0 μm (see FIG. 19A), depending on variations thereof.

TABLE 1

| Parameter | Value | |
|---|---|---|
| Wavelength | 10.6 | μm |
| Type of scanning | Line scanning | |
| Scanning speed | 7 | cm/seconds |
| Laser beam size | Length: 12 nm; Width: 150 μm | |
| Repetition rate | 10000 | Hz |
| Time period | 10 | μs |
| Duty cycle | 10% | |
| Output power | 90 | W |

### Comparative Example 1 (CE1)

The method for manufacturing a semiconductor device of CE1 is substantially similar to that of E1, except that in CE1, the selective annealing process and the cooling process were omitted.

### Example 2 (E2)

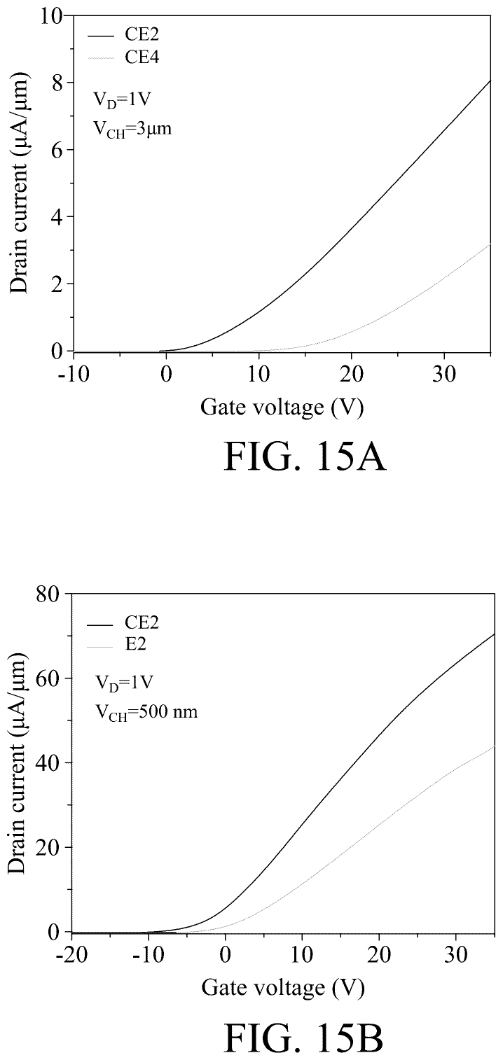

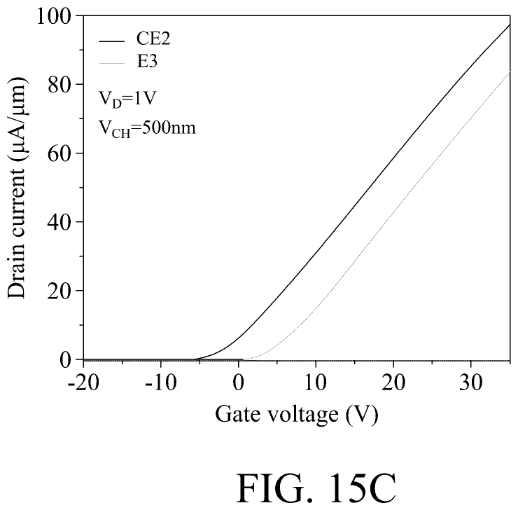

The method for manufacturing a semiconductor device of E2 was implemented according to the aforesaid second embodiment of the present disclosure. To be specific, before depositing the Bi layer on the two regions of the MoS₂ two-dimensional material layer, a shutter of the electron beam evaporator was used to cover a bottom part of the MoS₂ two-dimensional material layer, and after the bottom part of the MoS₂ two-dimensional material layer is covered by the shutter, the power of an electron gun of the electron beam evaporator was turned on to generate an electron beam facing a crucible so as to bombard a Bi block material therein, thereby allowing a bismuth monoxide (BiOx) film formed on a surface of the Bi block material to be deposited on the shutter. After the BiOx film on the surface of the Bi block material was completely removed, the shutter was removed, and the electron beam continues to bombard the Bi block material (i.e., regardless of whether the shutter was removed or not, the electron beam continues to bombard the Bi block material), so as to deposit the 10 nm Bi layer on the two regions of the MoS₂ two-dimensional material layer. Hence, deposition of the BiOx on the MoS₂ two-dimensional material layer which affects electrical performance of the semiconductor device of E2 can be avoided. Next, a 30 nm Ni layer was deposited by evaporation on the 10 nm Bi layer, followed by subjecting the two double-layer metal structures to the selective annealing process as described in E1. The output power and the scanning speed in the selective annealing process were 80 W and 5 cm/seconds, respectively. It should be noted that, in the manufacturing method of E2, the MoS₂ two-dimensional material layer served as the channel layer of the semiconductor device, and the channel layer had a length of 3.0 μm (not shown), 500 nm (see FIG. 15B) or 200 nm (not shown), depending on variations thereof.

### Example 3 (E3)

The method for manufacturing a semiconductor device of E3 was implemented according to the aforesaid third embodiment of the present disclosure, and is substantially similar to that of E2, except that in E3, the scanning speed in the selective annealing process was 7 cm/seconds.

### Comparative Example 2 (CE2)

The method for manufacturing a semiconductor device of CE2 is substantially similar to that of E2, except that in CE2, the selective annealing process and the cooling process were omitted.

### Comparative Example 3 (CE3)

The method for manufacturing a semiconductor device of CE3 is substantially similar to that of E2, except that in CE3, the selective annealing process was replaced with a rapid thermal annealing (RTA) process. In the manufacturing method of CE3, the RTA process was conducted by heating the two double-layer metal structures to 400° C. at a heating rate of 10° C./seconds for 60 seconds.

### Comparative Example 4 (CE4)

The method for manufacturing a semiconductor device of CE4 is substantially similar to that of CE3, except that in CE4, the RTA process was conducted by heating the two double-layer metal structures to 300° C. for 30 seconds.

### Example 4 (E4)

The method for manufacturing a semiconductor device of E4 is substantially similar to that of E2, except that in E4, a 50 nm Au layer is deposited on the Bi layer by evaporation.

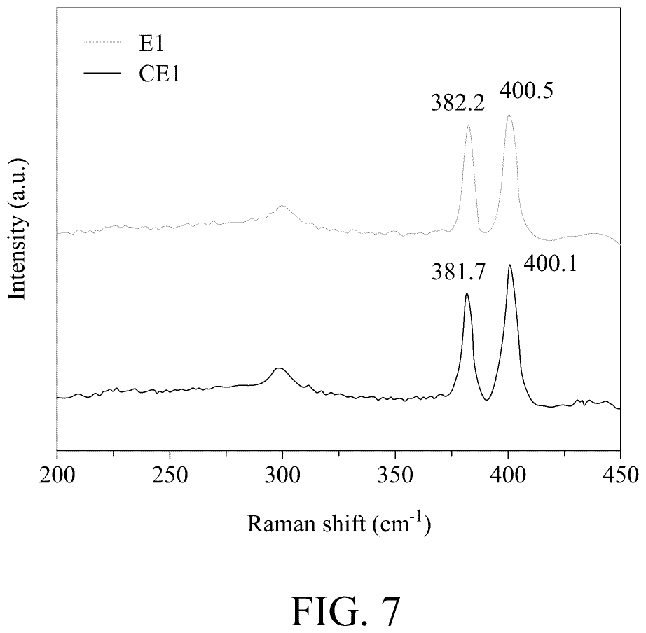

Referring to the Raman spectra shown in FIG. 7, the positions of peak signals of the MoS₂ two-dimensional material layer of CE1 were similar to those of the MoS₂ two-dimensional material layer of E1, indicating that the MoS₂ two-dimensional material layer of E1 was not damaged by the CO₂ laser after the selective annealing process.

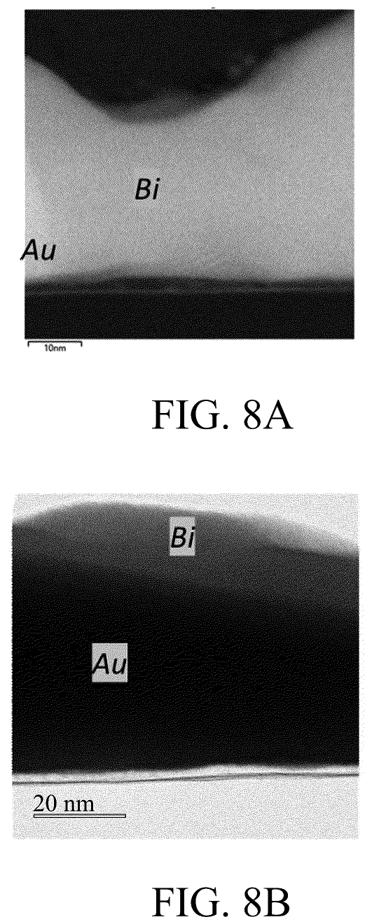

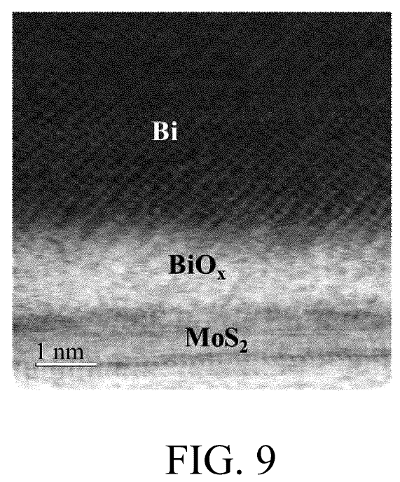

Referring to the transmission electron microscopy (TEM) images of cross-sectional views of the semiconductor device shown in FIGS. 8A and 8B and to the high-resolution transmission electron microscopy (HRTEM) image of a cross-sectional view of Bi single crystal parts of the semiconductor device shown in FIG. 9, after the selective annealing process and the cooling process, the Bi in the alloyed structure was precipitated on the side regions of the Au (see FIG. 8A) and on an upper surface of the Au (see FIG. 8B) of the semiconductor device of E1, and the thus precipitated Bi was in the form of single crystals (see FIG. 9). It should be noted that, the results shown in FIGS. 8A and 8B (i.e., determination of the locations of the Bi and Au in the semiconductor device) were obtained by analysis using an energy dispersive spectrometer (EDS) in combination with the TEM equipment.

Referring to the electrical property data shown in FIG. 10A, the current density of the semiconductor device of E1 was approximately 42% higher than that of semiconductor device of CE1.

The data shown in FIG. 10A were subjected to analysis by the transfer length method (TLM) so as to determine the contact resistances (R_{c}) of the semiconductor devices of E1 and CE1 which were shown in FIG. 10B. It should be noted that the carrier concentration required for the TLM was 8.64×10¹²/cm². As shown in FIG. 10B, the contact resistance (R_{c}) of the semiconductor device of CE1 was as high as 46.5 kΩ·μm, whereas the contact resistance (R_{c}) of the semiconductor device of E1 was merely 35 kΩ·μm.

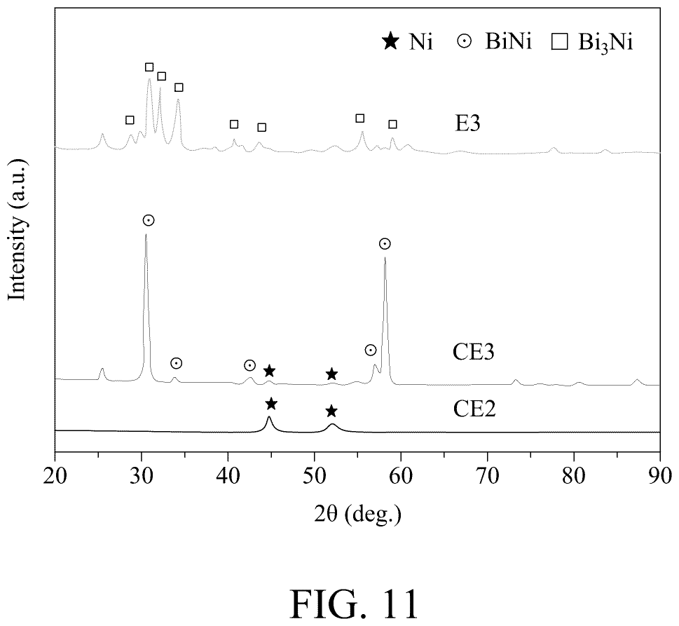

FIG. 11 is a diagram showing grazing-incidence X-ray diffraction (GIXRD) for the crystal structures of the semiconductor devices obtained by the methods of E3, CE2, and CE3. In the GIXRD, an incident angle of the X-ray with respect to each of the semiconductor devices of E3, CE2, and CE3 was set to 0.5 degrees. As shown in FIG. 11, the crystal structures of CE2, which was not subjected to selective annealing process, only exhibited diffraction peak signals of Ni, indicating that only Ni crystalline phase was present in CE2; the crystal structures of CE3, which was subjected to the RTA process at 400° C. for 60 seconds, exhibited both diffraction peak signals of Ni and BiNi, indicating that Ni crystalline phase and BiNi crystalline phase were present in CE3; and the crystal structures of E3, which was subjected to the selective annealing process at the scanning speed of 7 cm/min and the output power of 80 W, only exhibited diffraction peak signals of Bi₃Ni, indicating that a portion of the double-layer metal structure of E3 was transformed into Bi₃Ni crystalline phase after the CO₂ laser annealing process and the cooling process.

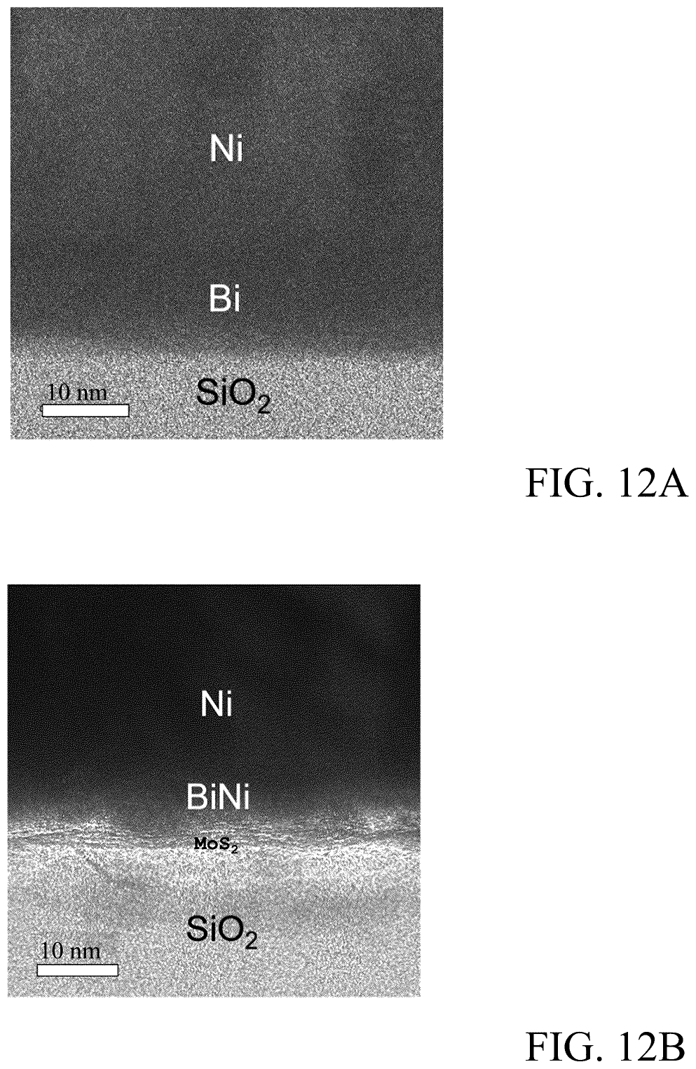

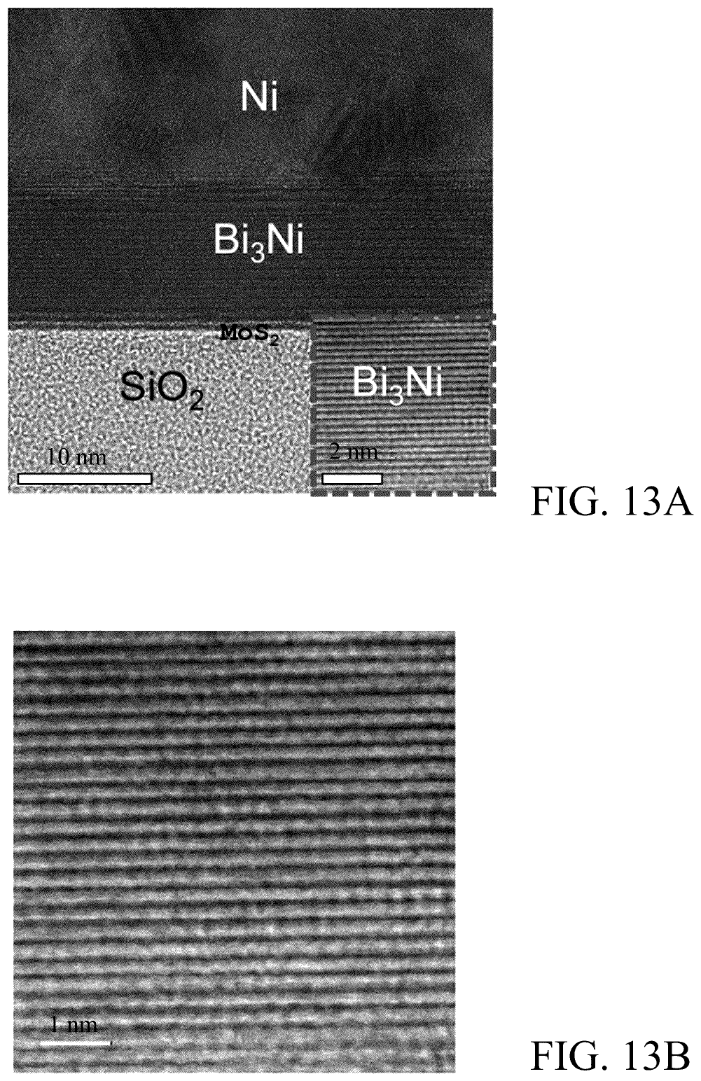

FIGS. 12A and 12B are TEM images of the cross-sectional view of the semiconductor devices obtained by the manufacturing methods of CE2 and CE4, respectively. As shown in FIG. 12A, the Bi layer and the Ni layer are sequentially stack on the SiO₂ layer, and as shown in FIG. 12B, the BiNi layer and the Ni layer were sequentially stacked on the MoS₂ two-dimensional material layer opposite to the SiO₂ layer. It should be noted that, the region representing the MoS₂ two-dimensional material layer was not captured during TEM imaging of the semiconductor device of CE2, and thus the MoS₂ two-dimensional material layer of the semiconductor device of CE2 was not shown in FIG. 12A.

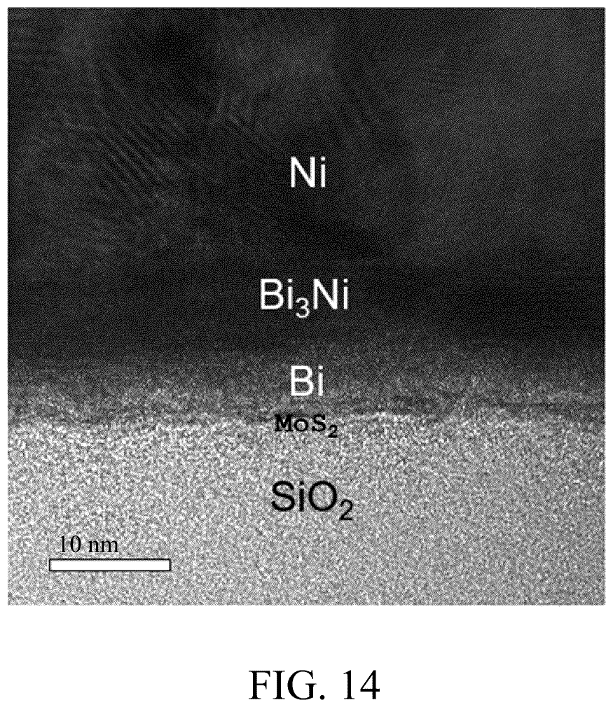

FIGS. 13A and 13B are TEM images of the cross-sectional view of the semiconductor device obtained by the manufacturing method of E2 that includes the selective annealing process conducted at the scanning speed of 5 cm/min and the output power of 80 W. As shown in FIGS. 13A and 13B, the Bi₃Ni single crystal part composed of a plurality of the Bi₃Ni layers are stacked on the MoS₂ two-dimensional material layer opposite to the SiO₂ layer, and a distance between two adjacent ones of the Bi₃Ni layers of the Bi₃Ni single crystal part of E2 is calculated to be approximately 0.242 nm. FIG. 14 is a TEM image of the cross-sectional view of the semiconductor device obtained by the manufacturing method of E3 that includes the selective annealing process conducted at the scanning speed of 7 cm/min and the output power of 80 W. As shown in FIG. 14, the Bi layer and the Bi₃Ni single crystal part composed of the plurality of the Bi₃Ni layers are sequentially stacked on the MoS₂ two-dimensional material layer opposite to the SiO₂ layer. The results shown in the FIGS. 13A, 13B and 14 indicate that, in the manufacturing method of E2, in which the two double-layer metal structures are subjected to the selective annealing process conducted at a relatively slow scanning speed (i.e., 5 cm/minute), all of the Bi of the Bi layer combined with the Ni of the Ni layer to form the Bi₃Ni single crystal part, whereas in the manufacturing method of E3, in which the two double-layer metal structures are subjected to the selective annealing process conducted at a relatively fast scanning speed (i.e., 7 cm/minute), only a portion of the Bi of the Bi layer is combined with the Ni of the Ni layer to form the Bi₃Ni single crystal part, and a remaining portion of the Bi of the Bi layer is in contact with the MoS₂ two-dimensional material layer opposite to the SiO₂ layer. It is worth to mention that, the melting point of the Bi₃Ni single crystal part obtained after the CO₂ laser annealing process in the manufacturing methods of E2 and E3 is higher than the melting point of the Bi obtained in the manufacturing method of in CE2, indicating that the thermal stability of the semiconductor devices of E2 and E3 is higher than that of the semiconductor device of CE2 (results regarding the thermal stability test for the semiconductor devices will be described hereinafter). It should be noted that, the results shown in FIGS. 12A, 12B, 13A and 14 (i.e., TEM images showing cross-sectional views of the semiconductor devices of CE2, CE4, E2 and E3, and determination of the locations of the Ni, Bi, BiNi, Bi₃Ni and MoS₂ in such semiconductor devices) were obtained by analysis using an EDS in combination with the TEM equipment.

Based on the analysis of the results shown in FIGS. 15A, 15B and 15C, the carrier mobility (μFE) of the semiconductor device of CE4 (including the BiNi layer) decreased from 12.8 cm²/V·s to 8.3 cm²/V·s, and the μFE of the semiconductor device of E2 (including the Bi₃Ni single crystal part) decreased from 14.3 cm²/V·s to 10.1 cm²/V·s. In contrast, the semiconductor device of E3 (including the Bi₃Ni single crystal part in contact with the Bi layer) exhibited a relatively stable carrier mobility with a value thereof ranging from 19.5 cm²/V·s to 20.3 cm²/V·s.

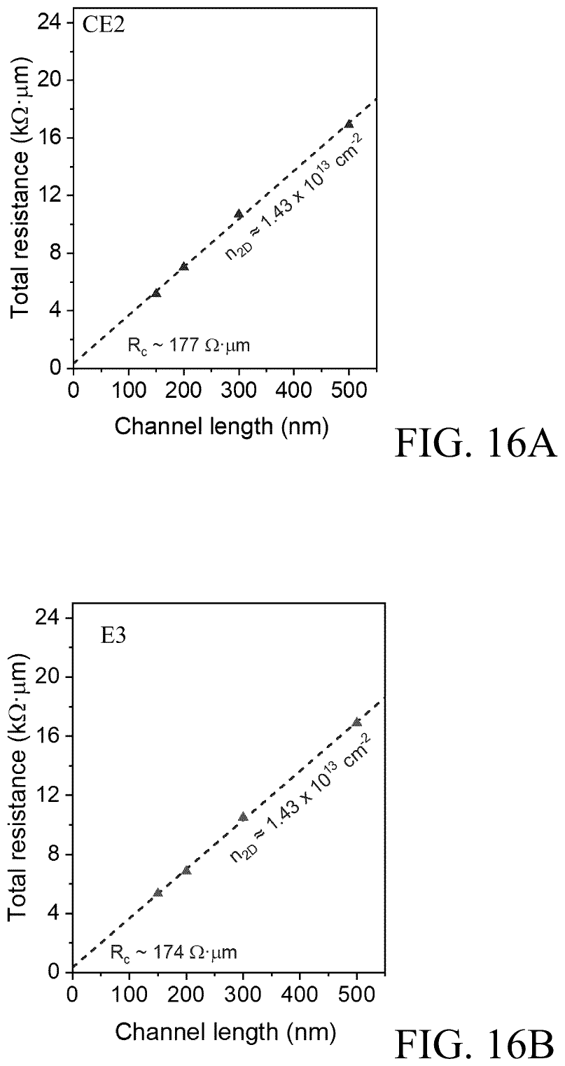

FIG. 16A illustrates the contact resistance (R_{c}) for the semiconductor device obtained by the manufacturing method of CE2 which is calculated by the TLM based on the graph of drain current versus gate voltage (not shown) and the graph of drain current versus drain voltage (not shown), and FIG. 16B illustrates the contact resistance (R_{c}) for the semiconductor device obtained by the manufacturing method of E3 which is calculated by the TLM based on the graph of drain current versus gate voltage (see FIG. 15C) and the graph of drain current versus drain voltage (not shown). It should be noted that the carrier concentration required for the TLM was 1.43×10¹³/cm². As shown in FIGS. 16A and 16B, the contact resistances (R_{c}) of the semiconductor devices of CE2 and E3 are similar, i.e., being 177 Ω·μm and 174 Ω·μm, respectively.

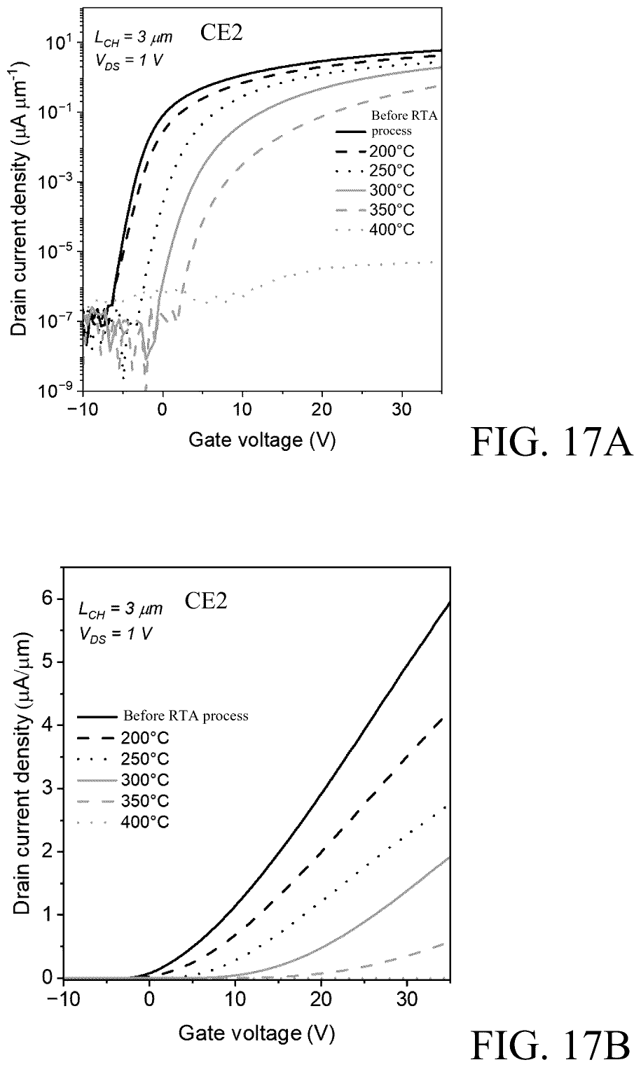

The results of the thermal stability test for the semiconductor devices obtained by the manufacturing methods of CE2, E3 and E1 were respectively shown in FIGS. 17A-17B, FIGS. 18A-18B and FIGS. 19A-19B. To be specific, each of the semiconductor devices of CE2, E3 and E1 was subjected to the RTA process conducted at different temperatures (i.e., temperature ranging from 200° C. to 500° C.) under a nitrogen atmosphere for 5 minutes each time, followed by measurement of current and voltage after each cycle of heating.

As shown in FIGS. 17A and 17B, when the source voltage (abbreviated as V_{DS} hereinafter) was 1 V, the slope of the linear region of the graphs of drain current density versus gate voltage decreased as the temperature of the RTA process increased, indicating that the contact resistance (R_{c}) of the semiconductor device of CE2 increased as the temperature of the RTA process increased. In addition, as shown in FIG. 17A, after conducting the RTA process one time at 400° C., the on/off ratio of the semiconductor device of CE2 decreased less than one order of magnitude, indicating that the electrical properties of the semiconductor device of CE2 significantly decreased after such RTA process.

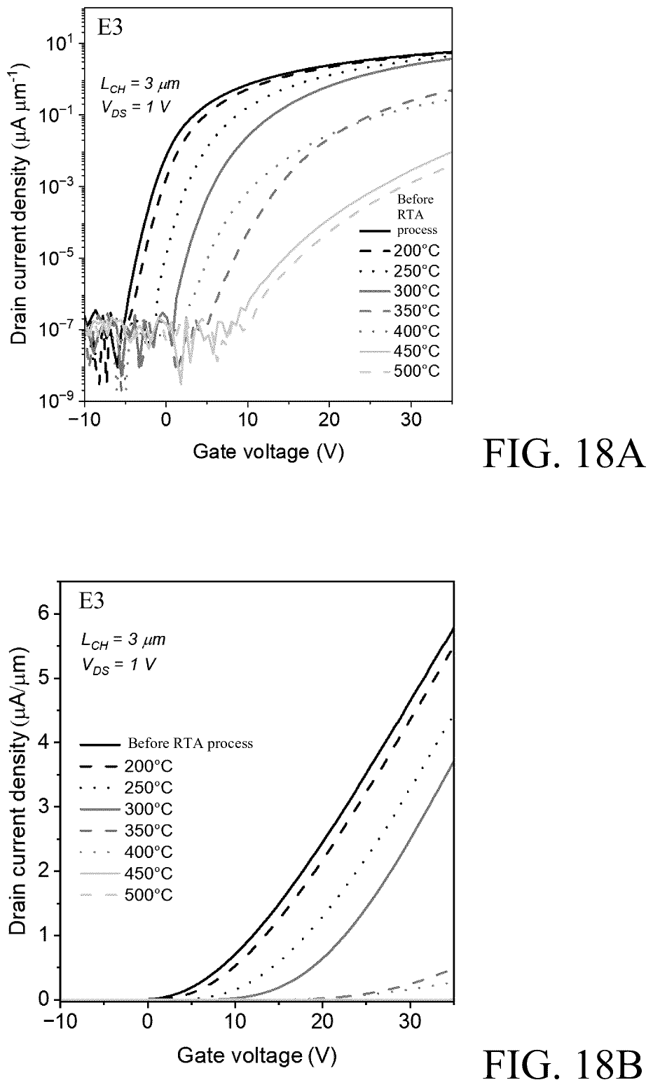

As shown in FIGS. 18A and 18B, when the V_{DS} was 1 V, although the slope of the linear region of the graphs of drain current density versus gate voltage decreased as the temperature of the RTA process increased, the slope of the linear region of the graphs of drain current density versus gate voltage for the semiconductor device of E3 did not changed much (i.e., remained stable) when the temperature of the RTA process increased to 300° C., and even after conducting the RTA process one time at 500° C., the on/off ratio of the semiconductor device of E3 was maintained to span four orders of magnitude (see FIG. 18A), confirming that the Bi₃Ni single crystal part in the semiconductor device of E3 is capable of providing excellent thermal stability with regard to electrical properties of the same.

As shown in FIGS. 19A and 19B, when the V_{DS} was 1 V, the slope of the linear region of the graphs of drain current density versus gate voltage for the semiconductor device of E1 decreased as the temperature of the RTA process increased. In addition, as shown in FIG. 19A, after conducting the RTA process one time at 350° C., the on/off ratio of the semiconductor device of E1 was less than one order of magnitude.

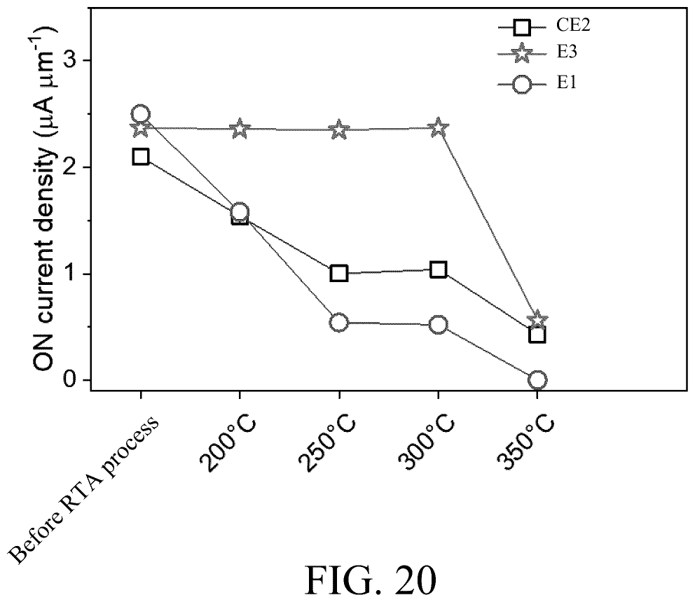

As shown in FIG. 20, after being subjected to the RTA process conducted at 200° C., 250° C. and 300° C. sequentially, the on-current density for the semiconductor device of E3 was still maintained at about 2.5 μA/μm without a downward trend. In contrast, after being subjected to the RTA process conducted at 200° C., 250° C. and 300° C. sequentially, the on-current densities for the semiconductor devices of CE2 and E1 showed a downward trend with only about 50% and 21% respectively, based on the on-current densities before the RTA process, remaining.

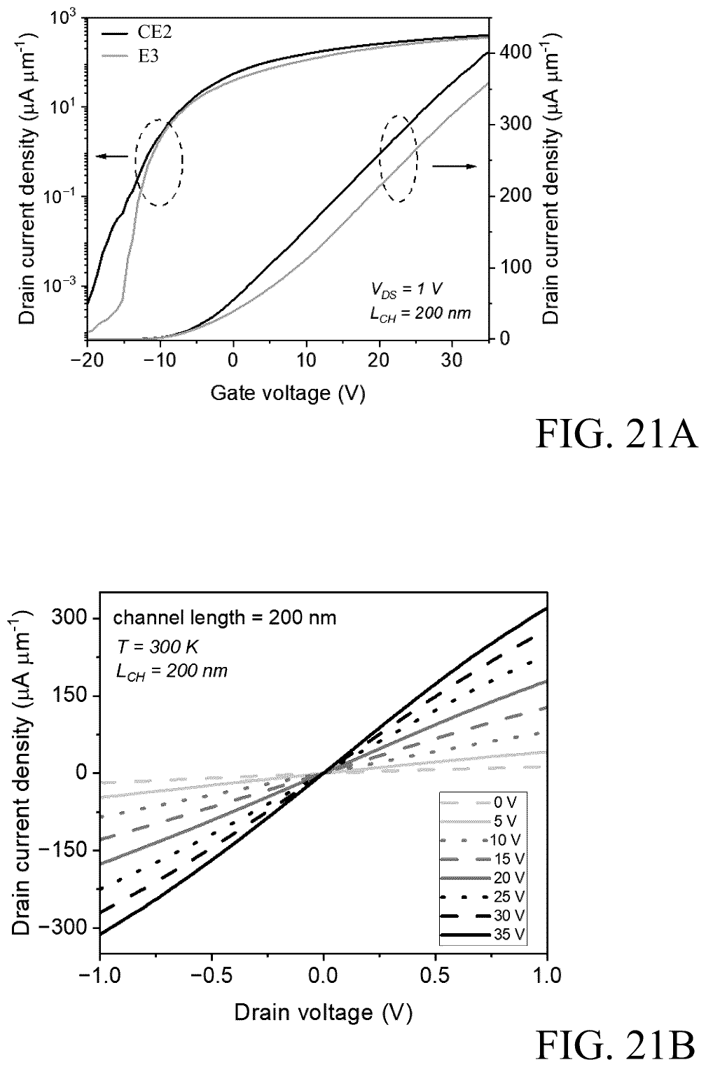

As shown in FIG. 21, both the carrier mobility and the on-current density for the semiconductor device of CE2 obtained without conducting the selective annealing process, and for the semiconductor device of E3 obtained after conducting the selective annealing process at the scanning speed of 7 cm/minute and the output power of 80 W, were similar. It should be noted that, the threshold voltage (abbreviated as Vth hereinafter) and the sub-threshold swing (abbreviated as S.S. hereinafter) for the semiconductor device of CE2 (obtained without conducting the selective annealing process) were −4.7 V and 1680 mV/decade, respectively, whereas the Vth and the S.S. for the semiconductor device of E3 (obtained after conducting the selective annealing process) were −0.7 V and 1020 mV/decade, respectively, which may be attributed to the selective annealing process being conducted in the manufacturing method of E3. In addition, as shown in FIG. 21B, the output characteristic for the semiconductor device of E3 clearly exhibited an ohmic contact behavior at the gate voltage ranging from 0 V to 35 V.

In summary, the method for manufacturing the semiconductor device of the present disclosure, in which each of the Bi single crystal layers 41 of the first metallic material is located on the two-dimensional material layer 3, are beneficial to reducing contact resistance (R_{c}) and increasing current density of the semiconductor device obtained by the method, and in which the Bi₃Ni single crystal parts of intermetallic compound 42 are formed, also help to improve thermal stability of the semiconductor device obtained by the method. Therefore, the purpose of the present disclosure can indeed be achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for manufacturing a semiconductor device, comprising the steps of:
(a) forming a two-dimensional material layer made of transition metal dichalcogenides on a semiconductor substrate unit;
(b) forming two lower metallic layers made of a first metallic material on the two-dimensional material layer, the two lower metallic layers being spaced apart from each other;
(c) forming two upper metallic layers made of a second metallic material respectively on the two lower metallic layers, so as to form two double-layer metal structures each including one of the upper metallic layers and a respective one of the two lower metallic layers; and
(d) subjecting the two double-layer metal structures to a selective annealing process, followed by cooling to room temperature, so as to form the two double-layer metal structures into a treated configuration,
wherein the first metallic material has a first melting point, the second metallic material has a second melting point, and the first melting point is lower than the second melting point,
wherein the treated configuration has one of a first configuration and a second configuration,
wherein the first configuration is obtained by alloying of the first metallic material and the second metallic material in the two double-layer metal structures during the selective annealing process to obtain two first alloyed structures, and cooling the two first alloyed structures to room temperature in a way that the two first alloyed structures are precipitated into two single crystal parts of the first metallic material and two first metal electrode layers of the second metallic material, the two single crystal parts of the first metallic material being formed over the two-dimensional material layer and being spaced apart from each other, each of the two first metal electrode layers of the second metallic material being in contact with a respective one of the two single crystal parts of the first metallic material, and
wherein the second configuration is obtained by alloying of the first metallic material and the second metallic material in the two double-layer metal structures during the selective annealing process to obtain two second alloyed structures, and cooling the two second alloyed structures to room temperature in a way that the two second alloyed structures are precipitated into two single crystal parts of intermetallic compound which are from at least one portion of the first metallic material and a first portion of the second metallic material in the two double-layer metal structures, and two second metal electrode layers of the second metallic material which are from a second portion of the second metallic material in the two double-layer metal structures, the two single crystal parts of the intermetallic compound being formed over the two-dimensional material layer and being spaced apart from each other, each of the two second metal electrode layers of the second metallic material being in contact with a respective one of the two single crystal parts of the intermetallic compound.

2. The method as claimed in claim 1, wherein the first metallic material is selected from Bi, Sb, In, Sn or Pb, and the second metallic material is selected from Au, Ni, Pt, Pd, Ti or Al, with the proviso that Al is excluded as the second metallic material when the first metallic material is Bi or Sn, and with the proviso that Ni, Ti and Al are excluded as the second metallic material when the first metallic material is Pb.

3. The method as claimed in claim 2, wherein the first metallic material is Bi, and the second metallic material is Au or Ni.

4. The method as claimed in claim 2, wherein the first metallic material is Bi and the second metallic material is Ni, the intermetallic compound of each of the two single crystal parts being Bi₃Ni, each of the two single crystal parts of the intermetallic compound including a plurality of Bi₃Ni layers stacked along a thickness direction of the two-dimensional material layer, each of the two second metal electrode layers of the second metallic material being formed on an upper surface of a respective one of the two single crystal parts of the intermetallic compound.

5. The method as claimed in claim 4, wherein the treated configuration formed in step (d) has the second configuration, and in step (d), after cooling the two second alloyed structures to room temperature, two Bi contact layers are further formed from a remaining portion of the first metallic material in the two double-layer metal structures, each of the two Bi contact layers being sandwiched between the two-dimensional material layer and the respective one of the two single crystal parts of the intermetallic compound.

6. The method as claimed in claim 1, wherein each of the two lower metallic layers has a first thickness ranging from 1 nm to 20 nm.

7. The method as claimed in claim 1, wherein each of the two upper metallic layers has a second thickness ranging from 10 nm to 100 nm.

8. The method as claimed in claim 1, wherein the selective annealing process is a laser annealing process that is conducted on a top surface of each of the two double-layer metal structures, a laser light used in the laser annealing process having a predetermined wavelength ranging from 800 nm to 1 mm.

9. The method as claimed in claim 1, wherein the semiconductor substrate unit includes a doped semiconductor substrate and a dielectric layer formed on the doped semiconductor substrate.

10. A semiconductor device, comprising:
a semiconductor substrate unit;
a two-dimensional material layer formed on the semiconductor substrate unit and made of transition metal dichalcogenides;
two single crystal parts formed on the two-dimensional material layer and spaced apart from each other, the two single crystal parts being made of one of a first metallic material and an intermetallic compound that is composed of the first metallic material and a second metallic material; and
two metal electrode layers made of the second metallic material, each of the two metal electrode layers being in contact with a respective one of the two single crystal parts,
wherein the first metallic material has a first melting point, the second metallic material has a second melting point, and the first melting point is lower than the second melting point.

11. The semiconductor device as claimed in claim 10, wherein the first metallic material is selected from Bi, Sb, In, Sn or Pb, and the second metallic material is selected from Au, Ni, Pt, Pd, Ti or Al, with the proviso that Al is excluded as the second metallic material when the first metallic material is Bi or Sn, and with the proviso that Ni, Ti and Al are excluded as the second metallic material when the first metallic material is Pb.

12. The semiconductor device as claimed in claim 11, wherein the first metallic material is Bi, and the second metallic material is Au or Ni.

13. The semiconductor device as claimed in claim 11, wherein the first metallic material is Bi and the second metallic material is Ni, the two single crystal parts being made of the intermetallic compound, the intermetallic compound of each of the two single crystal parts being Bi₃Ni, each of the two single crystal parts of the intermetallic compound including a plurality of Bi₃Ni layers stacked along a thickness direction of the two-dimensional material layer, each of the two metal electrode layers of the second metallic material being formed on an upper surface of a respective one of the two single crystal parts of the intermetallic compound.

14. The semiconductor device as claimed in claim 13, further comprising two Bi contact layers, each of the two Bi contact layers being sandwiched between the two-dimensional material layer and the respective one of the two single crystal parts of the intermetallic compound.

15. The semiconductor device as claimed in claim 10, wherein the semiconductor substrate unit includes a doped semiconductor substrate and a dielectric layer formed on the doped semiconductor substrate.
